(19) United States
(12) Patent Application Publication
(10) Pub. No.: US 2026/0338853 A1
(43) Pub. Date: Oct. 29, 2026

(54) DETECTING ENVIRONMENAL VARIATION OF COMPONENT VALUES IN AN ELECTRONIC CIRCUIT DUE TO CIRCUIT BOARD INSTALLATION-INDUCED MECHANICAL STRESS

(71) Applicant: CIRRUS LOGIC INTERNATIONAL SEMICONDUCTOR LTD., Edinburgh (GB)

(72) Inventors: Johnny Klarenbeek, Austin, TX (US); Tonmoy Roy, Pflugerville, TX (US); Anindya Bhattacharya, Austin, TX (US); Bhoodev Kumar, Bee Cave, TX (US); John L. Melanson, Austin, TX (US)

(21) Appl. No.: 19/647,514

(22) Filed: Apr. 14, 2026

Related U.S. Application Data
(60) Provisional application No. 63/793,863, filed on Apr. 24, 2025.

(51) Int. Cl. G01R 31/28

(52) U.S. Cl. CPC G01R 31/2817; G01R 31/2813

(57) ABSTRACT

A method of detecting environmental variation of a value of a component of an electronic circuit, includes detecting circuit board installation-induced mechanical stress. Prior to circuit board installation, a first value of the component is obtained by applying an internal reference of a feedback DAC of an ADC, or a reference waveform to the ADC and reading its output. The internal reference is a reference voltage or current of the feedback DAC used in performing conversions after circuit board installation. The result is stored in non-volatile storage, and subsequent to installation on a printed circuit board, at any time during operational lifetime, a second indication of a second value of the component is obtained by applying the reference to the input of the ADC and reading the output of the ADC. The first indication and second indication are compared to measure environmental variation of the value of the component.

### FIELD OF THE DISCLOSURE

The field of representative embodiments of this disclosure relates to calibration of analog integrated circuits, and in particular to a method and system that calibrate circuits depending on external components that are subject to circuit board installation-induced mechanical stress, or thermal and other environmental factors that introduce component value variations.

### BACKGROUND

Integrated circuits incorporating measurement or sensor receivers typically have a gain and offset dependency that may involve external/internal passive components, such as gain or offset-setting resistors, including input resistors for integrating and amplifying circuits, and the like. In particular, continuous-time delta-sigma modulator circuits are very sensitive to component variations, in particular the input resistor resistances and feedback capacitor capacitances. While such a circuit may be calibrated after the printed circuit board (PCB) component population manufacturing stage, ideally calibration would be performed at the chip or die manufacturing stage. Such calibration is ineffective to environmental stresses that cause component value changes only after PCB installation, and run-time calibration of some sort is generally needed.

While compensation for thermal variation by temperature sensing and digital compensation of internal parameters may be used to correct for environmental variations in component values, it may not be practical to sense and correct for mechanical stresses, since those stresses may vary by individual component location and characteristics. For example, even integrated on a die, package stresses may cause changes in resistor or capacitor arrays, e.g., polysilicon resistors integrated on a die.

Therefore, it would be advantageous to provide a calibration method that is able to calibrate circuits for variation such as component mechanical stress induced-variation that may be performed during run-time operation and without disruption of operation of the circuit.

### SUMMARY

The objective of providing a calibration method capable to run-time calibrate circuits for variation such as component mechanical stress induced-variation during without disruption of operation of the circuit is accomplished in calibration methods and circuits.

The methods and circuits detect environmental variation of a value of a component of an integrated circuit, including circuit board installation-induced mechanical stress. In some embodiments, the method includes: at a component manufacturing stage prior to circuit board installation, first obtaining a first indication of a first value of the component by applying an internal reference of a feedback digital-to-analog converter (DAC) of an internal analog-to-digital converter (ADC) to the input of the ADC and reading an output of the ADC. The internal reference is a reference voltage or current of the DAC used in performing digital-to-analog conversions after circuit board installation. The method also includes storing the first indication in a non-volatile storage of the electronic circuit, and subsequent to installing the electronic circuit on a printed circuit board and at any time during an operational lifetime of the component, obtaining a second indication of a second value of the component by applying the internal reference to the input of the ADC and reading the output of the ADC, and comparing the first indication to the second indication to obtain a measure of the environmental variation of the value of the component.

In other embodiments, the method includes: at a component manufacturing stage prior to circuit board installation, first obtaining a first indication of a first value of the component by applying a calibration signal with predetermined amplitude according to an internal reference of the IC and reading an output of the ADC. The method includes storing the first indication in a non-volatile storage of the electronic circuit, and subsequent to installing the electronic circuit on a printed circuit board and at any time during an operational lifetime of the component, obtaining a second indication of a second value of the component by applying the internal reference to the input of the ADC and reading the output of the ADC, and comparing the first indication to the second indication to obtain a measure of the environmental variation of the value of the component. The signal generating circuit may include a pseudo-random sequence generator, and the controller may obtain the second indication of the second value of the component by reading an output of the ADC and processing the output of the ADC in conformity with an output of the pseudo-random sequence generator to detect the second indication of the second value of the component.

The summary above is provided for brief explanation and does not restrict the scope of the claims. The description below sets forth example embodiments according to this disclosure. Further embodiments and implementations will be apparent to those having ordinary skill in the art. Persons having ordinary skill in the art will recognize that various equivalent techniques may be applied in lieu of, or in conjunction with, the embodiments discussed below, and all such equivalents are encompassed by the present disclosure.

### BRIEF DESCRIPTION OF THE DRAWINGS

FIG. 1A is a pictorial diagram illustrating an example factory calibration system 10, in accordance with an embodiment of the disclosure.

FIG. 1B is a pictorial diagram illustrating an example printed circuit board assembly 15, in accordance with an embodiment of the disclosure.

FIG. 2A is a block diagram illustrating an example factory test system 25, in accordance with an embodiment of the disclosure.

FIG. 2B is a block diagram illustrating an example system 35, in accordance with an embodiment of the disclosure.

FIG. 3 is a simplified schematic diagram illustrating details of an example measurement system 40, in accordance with an embodiment of the disclosure.

FIG. 4 is a flowchart 50 illustrating example operation of example measurement system 50 of FIG. 3, in accordance with another embodiment of the disclosure.

FIG. 5 is a simplified schematic diagram illustrating details of another example measurement system 60, in accordance with another embodiment of the disclosure.

### DETAILED DESCRIPTION

The present disclosure encompasses methods, circuits and integrated circuits, capable of evaluating, and compensating for, environmental variations in a value of a component of an integrated circuit, includes detecting circuit board installation-induced mechanical stress. Prior to circuit board installation, a first value of the component is obtained by applying an internal reference of a feedback digital-to-analog converter (DAC) of an analog-to-digital converter (ADC) to the internal ADC and reading its output. The internal reference is a reference voltage or current used in performing conversions after circuit board installation. The first indication is stored in non-volatile storage, and subsequent to installation on a printed circuit board, and at any time of the component's operational lifetime, a second indication of a second value of the component is obtained by applying the feedback DAC's internal reference to the input of the ADC and reading the output of the ADC. The method compares the first indication to the second indication to obtain a measure of the environmental variation of the value of the component.

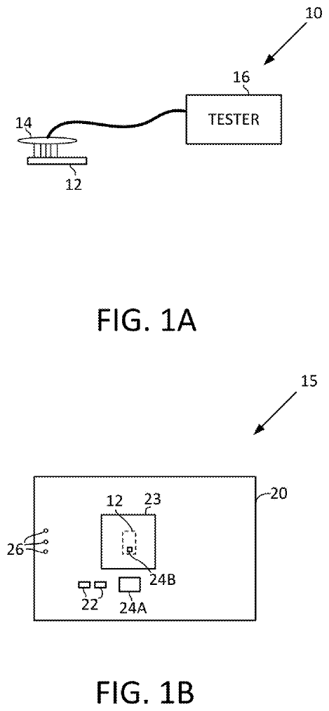

Referring now to FIG. 1A, a pictorial diagram illustrating an example factory calibration system 10, is shown in accordance with an embodiment of the disclosure. An integrated circuit 12, which may be a die on a wafer, a singulated die, or a packaged die, is connected to a tester 16, which is generally a general-purpose or special purpose computer with appropriate digital and analog interfaces, by a tester head 14, which may include probes for die-level or wafer-level connections to integrated circuit 12, or for coupling to terminals of a package of integrated circuit 12. Tester 16 operates integrated circuit 12 to collect digital values corresponding to a reference measurement as described below, and to store representations of the reference measurement values in a non-volatile storage of integrated circuit 12 for subsequent evaluation of change of component values that indicate a variation in component values due to environmental changes, in particular changes in component values due to mechanical stresses that occur after installation of integrated circuit 12 on a printed circuit board (PCB). In other embodiments in which detection of and/or compensation for, variation due to environmental stresses on other components on PCB, the factory calibration values may be obtained after PCB assembly and stored at that time.

Referring now to FIG. 1B, a pictorial diagram illustrating an example PCB assembly 15, is shown in accordance with an embodiment of the disclosure. PCB assembly 15 includes integrated circuit 12 in the form of a die that is included in a package 23 attached to a PCB 20 via terminals of package 23, which may be, for example balls of a solder-ball type attach, leads of a leaded package, wire bond attachments directly from a die (die-on-substrate construction) or any other suitable interconnect between integrated circuit 12 and other components installed on PCB 20, e.g., discrete resistors or capacitors 22, resistor or capacitor arrays 24A, and the like. Integrated circuit 12 may also integrate resistor and/or capacitor arrays 24B that may be affected by mechanical stresses on package 23 that occur across terminal connections to PCB 20. Examples of integrated circuit 12 as described herein below may include measurement circuits having analog-to-digital converters (ADCs) that are connected to components of PCB assembly 15 and may be connected to other components/signals via terminals 26 provided on PCB 20.

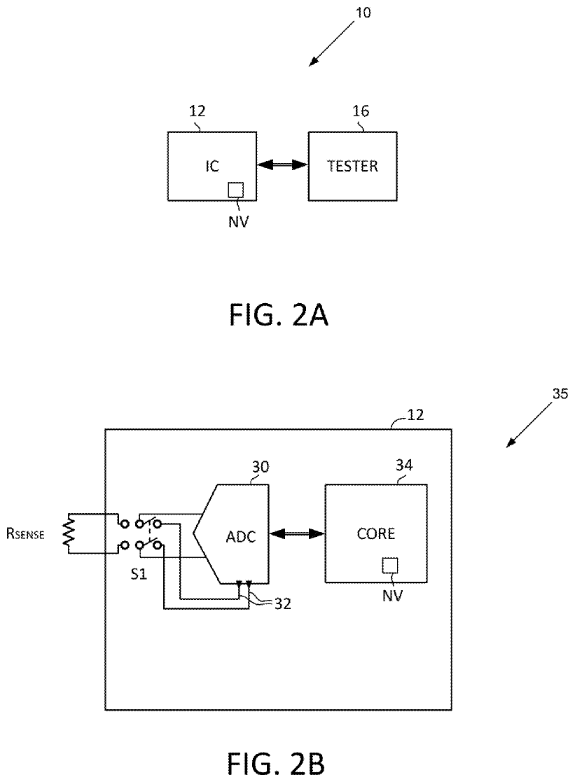

Referring now to FIG. 2A, a block diagram illustrating an example factory test system 25, is shown in accordance with an embodiment of the disclosure. As described above with reference to FIG. 1A, IC 12 is connected to tester 16 by a number of electrical signals that permit tester 16 to cause measurement of digital values of analog signals, and store values corresponding to measurements made of, for example, offset and gain values of circuits of integrated circuit 12, in non-volatile storage NV that are used subsequent to installation of integrated circuit 12 on a PCB, to determine changes by comparison to similar/identical measurements of the values during the operational lifetime of integrated circuit 12.

Referring now to FIG. 2B, a block diagram illustrating an example system 35, is shown in accordance with an embodiment of the disclosure. A measurement resistor R_{SENSE}, which may be a current-sensing resistor, a thermistor or a resistance measuring another quantifiable condition, such as a position, is connected to terminals of integrated circuit 12 that are coupled to a switch S1 that selects between measurement resistor R_{SENSE} and signals 32 provided from an ADC 30 and that are generated by the voltage or current reference of a DAC internal to ADC 30 that provides feedback signals for performing digital measurements of the signals received from switch S1. By using the reference of the feedback DAC independent of its feedback-related function, the reference circuits of ADC 30 is re-used to perform calibration measurements both at factory level, and during the operational life of IC 12 as described above. The operation avoids requiring a separate reference for the measurement, and more importantly, eliminates reference-to-reference drift in the measurements over the lifetime of IC 12. A core 34, which may be a microcontroller core, microprocessor, or a simple state machine may be included to collect digital output values from ADC 30, and may perform part or all of the functions described above with reference to tester 16, and store/retrieve values from non-volatile storage NV both during factory test and during the operational life of IC 12. Core 34 may also store and retrieve values after processing by tester 16, by, for example, by serial communication with tester 16.

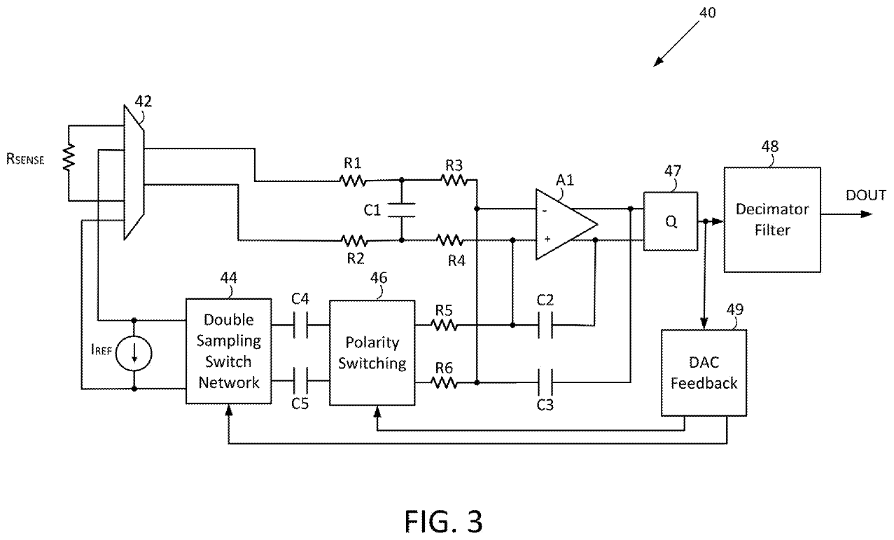

Referring now to FIG. 3, a simplified schematic diagram illustrating details of an example measurement system 40, is shown in accordance with an embodiment of the disclosure. Resistor R_{SENSE} is connected to a multiplexer 42 that is controlled by a control signal SEL that selects between the calibration mode, in which a feedback DAC current reference I_{REF}, but which may alternatively be a voltage reference, is coupled to the ADC input at resistors R1, R2, which in the operational mode are coupled to resistor R_{SENSE}. While details of the sensing circuit are not included here, in general, a current source or voltage source is coupled to resistor R_{SENSE} to cause a voltage to appear across resistor R_{SENSE}, representing an example value that may be measured under normal operation of example measurement system 40. The remainder of the ADC input circuit is provided by a capacitor C1 and resistors R3, R4, which together with resistors R1, R2 forms an anti-aliasing filter of an integrator that is completed by an amplifier A1 and feedback capacitors C2, C3. A quantizer (“Q”) 47 is coupled to the output of the integrator and provides values to control the magnitude of feedback DAC current reference I_{REF}, the output of which is supplied to a double-sampling switched-capacitor network 44, switched capacitor C4, C5 and a polarity-switching network 46 controlled by the sign of the output of quantizer 47, forming a feedback DAC. The feedback DAC provides the feedback value through resistors R5, R6, with a low level of IC-to-IC reference variation due to the double sampling action. A decimator filter block 48 provides the final digital output DOUT, which is generated from the output of quantizer 47. In general, all of the depicted measurement system with the exception of resistor R_{SENSE}, will be included in a single IC that performs ADC functions and that will also generally include a controller, such as core 34 of FIG. 2B, that implements the calibration and test methodologies at initial operation and at run-time. The factory portion of the calibration may be performed using an internal control mechanism such as core 34 of FIG. 2B, or may be performed using a tester or other factory-located system, such as tester 16 of FIG. 2a.

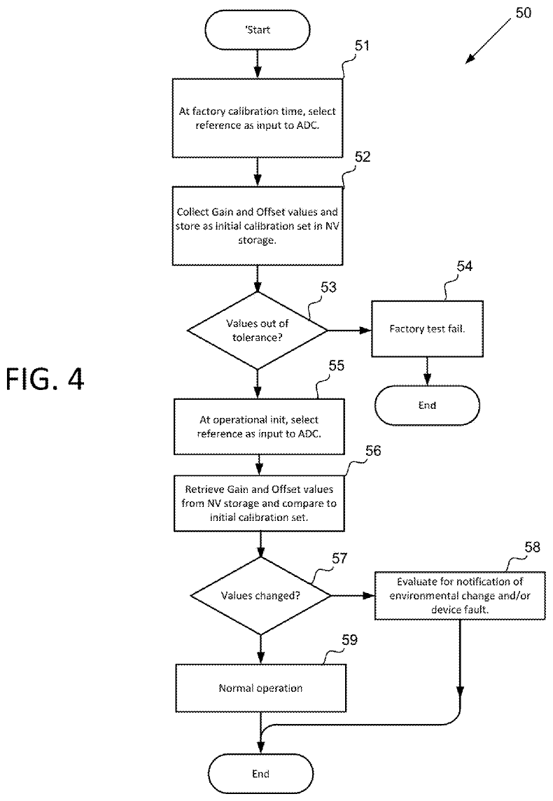

Referring now to FIG. 4, a flowchart 50 illustrating details an example operation of example measurement system 40 of FIG. 3, is shown in accordance with another embodiment of the disclosure. At factory calibration time, the reference is selected as the input to the ADC (step 51), then gain and offset values are collected and stored as an initial calibration set in NV storage (step 52). If the initial calibration set indicates that component values are out of tolerance (decision 53), the factory test may indicate failure (step 54), in which case the part would generally be removed from production. If the initial calibration set indicates that component values are within tolerance (decision 53), the parts are passed through for final encapsulation/assembly integration. At operational initialization, the reference is again selected as input to the ADC (step 55), then gain and offset values are retrieved from NV storage (step 56) and compared to the initial calibration set (step 56). If the values have changed substantially (decision 57), the differences may be evaluated to determine whether to notify, e.g., via a part error message or status indication and/or generate a device fault so that operation is discontinued (step 58). If the values have not changed substantially (decision 57), normal operation is commenced (step 59).

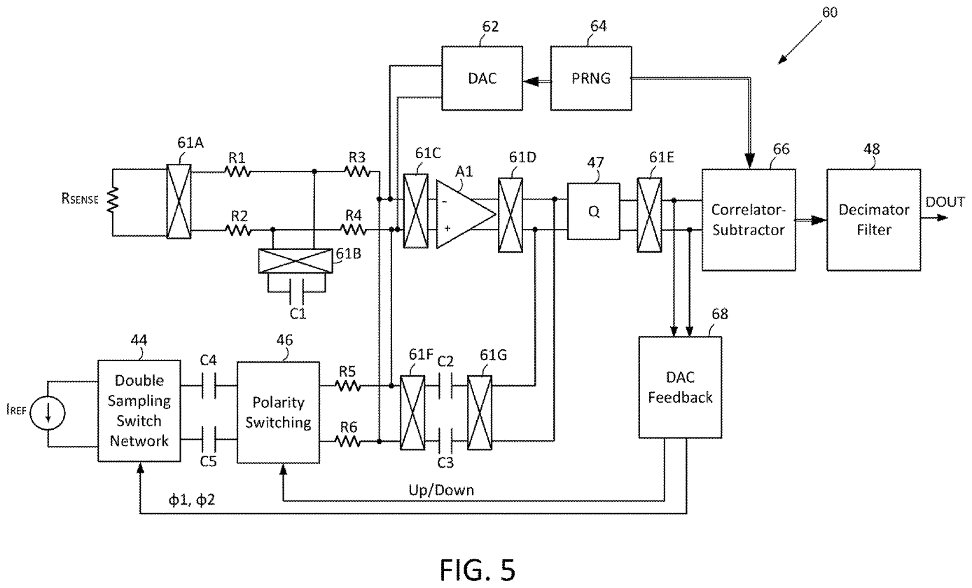

Referring now to FIG. 5, a simplified schematic diagram illustrating details of another example measurement system 60, is shown in accordance with another embodiment of the disclosure. Example measurement system 60 is similar to example measurement system 40 of FIG. 3, so only differences between their structure and operation will be described below. In example measurement system 60, the collection of the subsequent gain, offset, and/or other measurement values may be performed during normal operation without interfering with the operation of example measurement system 60. Therefore, rather than using the ADCs internal DAC reference, a separate DAC 62 is included to generate a reference calibration waveform that is combined with the input signal from resistor R_{SENSE}, and the reference calibration waveform may be isolated from the input signal via frequency characteristics and filtering, or by other means. In the illustrated example measurement system 60, a pseudo-random number generator (PRNG) 64 provides an input to DAC 62, which results in a superimposition of a pseudo-random waveform at the output of the integrator formed around amplifier A1, by injection of a differential current into the summing nodes (virtual ground). Therefore, the illustrated DAC 62 is a current-output DAC. Alternatively, a voltage-output DAC may be used, with resistors coupling the outputs of the DAC to the summing nodes. Also included in example measurement system 60 are a plurality of chopping switch networks (choppers) 61A-61G, which may also be included in example measurement system 40 of FIG. 3 at corresponding circuit locations. Choppers 61A-61G reduce differential circuit asymmetry and offset, and shift noise out of the measurement band. Choppers 61A and 61B chop the input sampling network and may be disabled when measuring only the reference calibration waveform, choppers 61C and 61D chop the input and output signals to and from amplifier A1 to remove in-band noise and offset. Choppers 61F and 61G chop feedback capacitor C2, C3 to remove asymmetry, and chopper 61E chops the output of quantizer 47 to reduce asymmetry and to shift noise out of band. A reference DAC feedback control block 68 receives the output of quantizer 47 and generates sign signal Up/Down that controls polarity switching block 46 and the switching phases provided to double-sampling switching network 44. A correlator-subtractor block 66 receives an output of PRNG, which may be delayed to time-align with the output of quantizer 47, and reconstructs the PRN waveform, which is then selectively removed from the output of quantizer, depending on whether the measurement input or the reference calibration waveform is being measured. The two streams may also be completely concurrent, so that no interruption in measurement of input values from resistor R_{SENSE} is needed at all.

In summary, this disclosure shows and describes methods and circuits that detect environmental variation of a value of a component of an electronic circuit, including circuit board installation-induced mechanical stress. In some example embodiments, the method includes: at a component manufacturing stage prior to circuit board installation, obtaining a first indication of a first value of the component by applying an internal reference of a feedback DAC of an internal ADC to the input of the ADC and reading an output of the ADC. The internal reference may be a reference voltage or current of the feedback DAC that is used in performing digital-to-analog conversions after circuit board installation. The methods may also include storing the first indication in a non-volatile storage of the electronic circuit, and subsequent to installing the electronic circuit on a printed circuit board and at any time during an operational lifetime of the component, obtaining a second indication of a second value of the component by applying the internal reference of the feedback DAC to the input of the ADC, reading the output of the ADC, and comparing the first indication to the second indication to obtain a measure of the environmental variation of the value of the component.

In some example embodiments, the electronic circuit may be an integrator having a capacitive feedback element, and the component may be an input resistor of the integrator, so that the capacitive feedback element is used in both the component manufacturing stage to obtain the first indication of the first value of the component, and during the operational lifetime of the component to obtain the second indication of the second value of the component, and wherein the value of the component is a resistance of the input resistor. In some example embodiments, the integrator may be an integrator of a delta-sigma modulator. In some example embodiments, the electronic circuit may be an amplifier having a resistive feedback element, and the component may be the resistive feedback element, so that the resistive feedback element is used in both the component manufacturing stage to obtain the first indication of the first value of the component, and during the operational lifetime of the component to obtain the second indication of the second value of the component. The value of the component may be a resistance of the resistive feedback element.

In some example embodiments, the method may further include determining whether or not the measure of the environmental variation of the value of the component indicates that a mechanical stress level applied to the component after circuit board installation exceeds a threshold stress level, and responsive to determining that the measure of the environmental variation of the value of the component indicates that the mechanical stress level applied to the component exceeds a threshold stress level, producing an error indication by the electronic circuit indicating that a board-level failure has occurred. In some example embodiments, the method may further include determining whether or not the measure of the environmental variation of the value of the component indicates that a mechanical stress level applied to the component after circuit board installation exceeds a threshold stress level, and responsive to determining that the measure of the environmental variation of the value of the component indicates that a stress level applied to the component exceeds a threshold stress level, preventing operation of the electronic circuit so that the electronic circuit is not operated with a board-level failure condition. In some example embodiments, the method may further include determining a gain compensation value for the electronic circuit from the measure of the environmental variation of the value of the component, and applying the gain compensation value to the electronic circuit, whereby circuit gain error due to the environmental variation is removed. In some example embodiments, the first obtaining of the first value of the component may obtain a first offset value of the electronic circuit. The second obtaining of the second value of the component may further obtain a second offset value of the electronic circuit. In some example embodiments, the method may further include determining an offset compensation value for the electronic circuit, and applying the offset compensation value to the electronic circuit, whereby circuit offset error due to the environmental variation is removed.

In some example embodiments, the obtaining of the first value of the component may obtain a first offset value of the electronic circuit, wherein the obtaining of the second value of the component may obtain a second offset value of the electronic circuit, and wherein the comparing further compares the first offset value to the second offset value to obtain the measure of the environmental variation of the value of the component.

In other example embodiments of the disclosure, the method may include at a component manufacturing stage prior to circuit board installation, first obtaining a first indication of a first value of the component by inserting a continuous input signal with a predetermined amplitude that has frequency characteristics that do not affect the run-time operation of the electronic circuit into an input of an analog-to-digital converter (ADC) of the electronic circuit and reading an output of the ADC, wherein the continuous input signal is generated from an internal reference. The method may further include storing the first indication in a non-volatile storage of the electronic circuit, and subsequent to installing the component on a printed circuit board and at any time during an operational lifetime of the component, second obtaining a second indication of a second value of the component by again injecting the continuous input signal and reading the output of the ADC. The method may then compare the first indication to the second indication to obtain a measure of the environmental variation of the value of the component.

In other example embodiments, the second obtaining the second value of the component may be performed continuously or periodically during a run-time operation of the electronic circuit. In some example embodiments, the obtaining of the second value of the component may be performed by inserting a continuous input signal with a predetermined amplitude that has frequency characteristics that do not affect the run-time operation of the electronic circuit into an input of the electronic circuit. In some example embodiments, the continuous input signal may be a signal having a characteristic controlled by a pseudo-random sequence generator, and the obtaining of the second indication of the value of the component may be performed by reading an output of the ADC and processing the output of the ADC in conformity with an output of the pseudo-random sequence generator to detect the second indication of the second value of the component.

As mentioned above, portions or all of the disclosed process may be carried out by a state machine, which may be provided by a logic circuit, or the execution of a collection of program instructions forming a computer program product stored on a non-volatile memory, and executed by a controller core. Such programs may also exist outside of the non-volatile memory in tangible forms of storage forming a computer-readable storage medium. The computer-readable storage medium may be, for example, but is not limited to, an electronic storage device, a magnetic storage device, an optical storage device, an electromagnetic storage device, a semiconductor storage device, or any suitable combination of the foregoing. Specific examples of the computer-readable storage medium include the following: a hard disk, semiconductor volatile and non-volatile memory devices, a portable compact disc read-only memory (CD-ROM) or a digital versatile disk (DVD), a memory stick, a floppy disk or other suitable storage device not specifically enumerated. A computer-readable storage medium, as used herein, is not to be construed as being transitory signals, such as transmission line or radio waves or electrical signals transmitted through a wire. It is understood that blocks of the block diagrams described above may be implemented by computer-readable program instructions. These computer readable program instructions may also be stored in other storage forms as mentioned above and may be downloaded into a non-volatile memory for execution therefrom. However, the collection of instructions stored on media other than the non-volatile memory described above also form a computer program product that is an article of manufacture including instructions which implement aspects of the functions/actions specified in the block diagram block or blocks, as well as method steps described herein.

While the disclosure has shown and described particular embodiments of the techniques disclosed herein, it will be understood by those skilled in the art that the foregoing and other changes in form, and details may be made therein without departing from the spirit and scope of the disclosure. For example, the techniques shown above may be applied to another type of circuit having associated external or internal components subject to mechanical stress or other environmental factor causing component variation after installation.

What is claimed is:

1. A method of detecting environmental variation a value of a component of an electronic circuit, including circuit board installation-induced mechanical stress, the method comprising:
at a component manufacturing stage prior to circuit board installation, first obtaining a first indication of a first value of the component by applying an internal reference of a feedback digital-to-analog converter (DAC) of an analog-to-digital converter (ADC) of an integrated circuit to an input of the ADC and reading an output of the ADC, wherein the internal reference is a reference voltage or current of the feedback DAC used in performing analog-to-digital conversions after circuit board installation;
storing the first indication in a non-volatile storage of the electronic circuit;
subsequent to installing the component on a printed circuit board and at any time during an operational lifetime of the component, second obtaining a second indication of a second value of the component by applying the internal reference of the feedback DAC to the input of the ADC and reading the output of the ADC; and
comparing the first indication to the second indication to obtain a measure of the environmental variation of the value of the component.

2. The method of claim 1, wherein the electronic circuit is an integrator having a capacitive feedback element, wherein the component is an input resistor of the integrator or the capacitive feedback element, whereby the capacitive feedback element and the input resistor are used in both the component manufacturing stage to obtain the first indication of the first value of the component as a first gain of the integrator and during the operational lifetime of the component to obtain the second indication of the second value of the component as a second gain of the integrator, and wherein the value of the component is a capacitance of the capacitive feedback element or the resistance of the input resistor.

3. The method of claim 2, wherein the integrator is an integrator of a delta-sigma modulator.

4. The method of claim 1, wherein the electronic circuit is an amplifier having a resistive feedback element, wherein the component is the resistive feedback element, whereby the resistive feedback element is used in both the component manufacturing stage to obtain the first indication of the first value of the component and during the operational lifetime of the component to obtain the second indication of the second value of the component, and wherein the value of the component is a resistance of the resistive feedback element.

5. The method of claim 1, further comprising:
determining whether or not the measure of the environmental variation of the value of the component indicates that a mechanical stress level applied to the component after circuit board installation exceeds a threshold stress level; and
responsive to determining that the measure of the environmental variation of the value of the component indicates that the mechanical stress level applied to the component exceeds a threshold stress level, producing an error indication by the electronic circuit indicating that a board-level failure has occurred.

6. The method of claim 1, further comprising:
determining whether or not the measure of the environmental variation of the value of the component indicates that a mechanical stress level applied to the component after circuit board installation exceeds a threshold stress level; and
responsive to determining that the measure of the environmental variation of the value of the component indicates that a stress level applied to the component exceeds a threshold stress level, preventing operation of the electronic circuit so that the electronic circuit is not operated with a board-level failure condition.

7. The method of claim 1, further comprising
determining a gain compensation value for the electronic circuit from the measure of the environmental variation of the value of the component; and
applying the gain compensation value to the electronic circuit, whereby circuit gain error due to the environmental variation is removed.

8. The method of claim 7, wherein the first obtaining of the first value of the component obtains a first offset value of the electronic circuit, wherein the second obtaining of the second value of the component further obtains a second offset value of the electronic circuit, and wherein the method further comprises:
determining an offset compensation value for the electronic circuit; and
applying the offset compensation value to the electronic circuit, whereby circuit offset error due to the environmental variation is removed.

9. The method of claim 1, wherein the first obtaining obtains a first offset value of the electronic circuit, wherein the second obtaining obtains a second offset value of the electronic circuit, and wherein the comparing further compares the first offset value to the second offset value to obtain the measure of the environmental variation of the value of the component.

10. A method of detecting environmental variation a value of a component of an electronic circuit, including circuit board installation-induced mechanical stress, the method comprising:
at a component manufacturing stage prior to circuit board installation, first obtaining a first indication of a first value of the component by inserting a reference calibration waveform that has frequency characteristics that do not affect the run-time operation of the electronic circuit into an input of an analog-to-digital converter (ADC) of the electronic circuit and reading an output of the ADC, wherein the reference calibration waveform is generated from an internal reference;
storing the first indication in a non-volatile storage of the electronic circuit;
subsequent to installing the component on a printed circuit board and at any time during an operational lifetime of the component, second obtaining a second indication of a second value of the component by again injecting the reference calibration waveform and reading the output of the ADC; and
comparing the first indication to the second indication to obtain a measure of the environmental variation of the value of the component.

11. The method of claim 10, wherein the second obtaining the second value of the component is performed continuously or periodically during a run-time operation of the electronic circuit.

12. The method of claim 11, wherein the second obtaining the second value of the component is performed by inserting a continuous waveform with a predetermined amplitude that has frequency characteristics that do not affect the run-time operation of the electronic circuit into an input of the electronic circuit.

13. The method of claim 12, wherein the continuous waveform is a signal having a characteristic controlled by a pseudo-random sequence generator, and wherein the second obtaining a second indication of the value of the component is performed by reading an output of the ADC and processing the output of the ADC in conformity with an output of the pseudo-random sequence generator to detect the second indication of the second value of the component.

14. An integrated circuit, comprising:
an analog-to-digital converter (ADC) including a feedback digital-to-analog converter (DAC) and an internal reference circuit of the feedback DAC that provides an internal feedback DAC reference for conversions during operation of the electronic circuit;
a non-volatile storage storing a first indication of a first value of a component of the electronic circuit obtained at a component manufacturing stage prior to circuit board installation by applying the internal feedback DAC reference to an input of the ADC and reading an output of the ADC;
a controller that subsequent to installation of the integrated circuit on a printed circuit board and at any time during an operational lifetime of the component, obtains a second indication of a second value of the component by applying the internal reference to the input of the ADC and reading the output of the ADC, and compares the first indication of the first value of the component to the second indication of the second value of the component to obtain a measure of the environmental variation of the value of the component.

15. The electronic circuit of claim 14, wherein the integrated circuit comprises an integrator having an input resistor and a capacitive feedback element, wherein the component is the input resistor or the capacitive feedback element of the integrator, whereby the input resistor and the capacitive feedback element are used in both the component manufacturing stage to obtain the first indication of the first value of the component as a first gain of the integrator and during the operational lifetime of the component to obtain the second indication of the second value of the component as a second gain of the integrator, and wherein the value of the component is a resistance of the input resistor or the capacitance of the capacitive feedback element.

16. The electronic circuit of claim 15, wherein the integrator is an integrator of a delta-sigma modulator.

17. The electronic circuit of claim 14, wherein the electronic circuit is an amplifier having a resistive feedback element, wherein the component is the resistive feedback element, whereby the resistive feedback element is used in both the component manufacturing stage to obtain the first indication of the first value of the component and during the operational lifetime of the component to obtain the second indication of the second value of the component, and wherein the value of the component is a resistance of the resistive feedback element.

18. The electronic circuit of claim 14, wherein the controller further determines whether or not the measure of the environmental variation of the value of the component indicates that a mechanical stress level applied to the component after circuit board installation exceeds a threshold stress level, and responsive to determining that the measure of the environmental variation of the value of the component indicates that the mechanical stress level applied to the component exceeds a threshold stress level, produces an error indication indicating that a board-level failure has occurred.

19. The electronic circuit of claim 14, wherein the controller further determines whether or not the measure of the environmental variation of the value of the component indicates that a mechanical stress level applied to the component after circuit board installation exceeds a threshold stress level, and responsive to determining that the measure of the environmental variation of the value of the component indicates that a stress level applied to the component exceeds a threshold stress level, prevents operation of the electronic circuit so that the electronic circuit is not operated with a board-level failure condition.

20. The electronic circuit of claim 14, wherein the controller further determines a gain compensation value for the electronic circuit from the measure of the environmental variation of the value of the component, and applies the gain compensation value to the electronic circuit, whereby circuit gain error due to the environmental variation is removed.

21. The electronic circuit of claim 20, wherein the controller further obtains first offset values of the electronic circuit and second offset values of the electronic circuit, determines an offset compensation value for the electronic circuit, and applies the offset compensation value to the electronic circuit, whereby circuit offset error due to the environmental variation is removed.

22. The electronic circuit of claim 14, wherein controller obtains first offset values of the electronic circuit and second offset values of the electronic circuit, and compares the one or more first offset values to the one or more second offset values to obtain the measure of the environmental variation of the value of the component.

23. An integrated circuit, comprising:
an analog-to-digital converter (ADC)
a signal generating circuit that generates a reference calibration waveform with predetermined amplitude according to an internal reference circuit;
a non-volatile storage storing a first indication of a first value of a component of the electronic circuit obtained at a component manufacturing stage prior to circuit board installation by applying the reference calibration waveform to an input of the ADC and reading an output of the ADC;
a controller that subsequent to installation of the integrated circuit on a printed circuit board and at any time during an operational lifetime of the component, obtains a second indication of a second value of the component by applying the reference calibration waveform to the input of the ADC and reading the output of the ADC, and compares the first indication of the first value of the component to the second indication of the second value of the component to obtain a measure of the environmental variation of the value of the component.

24. The electronic circuit of claim 23, wherein the controller obtains the second indication of the second value of the component continuously or periodically during a run-time operation of the electronic circuit.

25. The electronic circuit of claim 24, wherein the reference calibration waveform has a predetermined amplitude and has frequency characteristics that do not affect the run-time operation of the electronic circuit.

26. The electronic circuit of claim 25, wherein the signal generating circuit includes a pseudo-random sequence generator, and wherein controller obtains the second indication of the second value of the component by reading an output of the ADC and processes the output of the ADC in conformity with an output of the pseudo-random sequence generator to detect the second indication of the second value of the component.
